(19) United States
(12) Patent Application Publication
(10) Pub. No.: US 2024/0143179 A1
(43) Pub. Date: May 2, 2024

(54) RESUMING SUSPENDED PROGRAM OPERATIONS IN A MEMORY DEVICE

(71) Applicant: Micron Technology, Inc., Boise, ID (US)

(72) Inventors: Keng Gee Ng, Singapore (SG); Mohammed Musaiyab Tarapati, Singapore (SG)

(21) Appl. No.: 18/489,775

(22) Filed: Oct. 18, 2023

Related U.S. Application Data
(60) Provisional application No. 63/420,051, filed on Oct. 27, 2022.

(51) Int. Cl. G06F 3/06

(52) U.S. Cl. CPC G06F 3/0611; G06F 3/0659; G06F 3/0679

(57) ABSTRACT

Control logic in a memory device, responsive to receiving a request to resume a previously suspended memory access operation, initiates a program verify operation on a memory cell of the memory device, such as a memory cell that was at least partially programmed during the previously suspended memory access operation. The control logic further determines whether the memory cell passes the program verify operation. Responsive to determining that the memory cell does not pass the program verify operation, the control logic identifies a program level group of a plurality of program level groups with which the memory cell is associated and determines a resume program offset value associated with the program level group, wherein each of the plurality of program level groups has a different respective resume program offset value. The control logic can further cause a programming pulse to be applied to the memory cell to resume the previously suspended memory access operation, wherein a magnitude of the programming pulse is based on the resume program offset value associated with the program level group.

### RELATED APPLICATIONS

This application claims the benefit of U.S. Patent Application No. 63/420,051, filed Oct. 27, 2022, the entire contents of which are hereby incorporated by reference herein.

### TECHNICAL FIELD

Embodiments of the disclosure relate generally to memory sub-systems, and more specifically, relate to resuming suspended program operations in a memory device of a memory sub-system.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The present disclosure will be understood more fully from the detailed description given below and from the accompanying drawings of various embodiments of the disclosure.

FIG. 1A illustrates an example computing system that includes a memory sub-system in accordance with some embodiments of the present disclosure.

FIG. 1B is a block diagram of a memory device in communication with a memory sub-system controller of a memory sub-system, in accordance with some embodiments of the present disclosure.

FIG. 2 is a schematic of portions of an array of memory cells as could be used in a memory of the type described with reference to FIG. 1B in accordance with some embodiments of the present disclosure.

FIG. 3 is a flow diagram of an example method of resuming suspended program operations in a memory device of a memory sub-system in accordance with some embodiments of the present disclosure.

FIG. 4 is a flow diagram of an example method of suspending program operations in a memory device of a memory sub-system in accordance with some embodiments of the present disclosure.

FIG. 5 is a block diagram of an example computer system in which embodiments of the present disclosure can operate.

### DETAILED DESCRIPTION

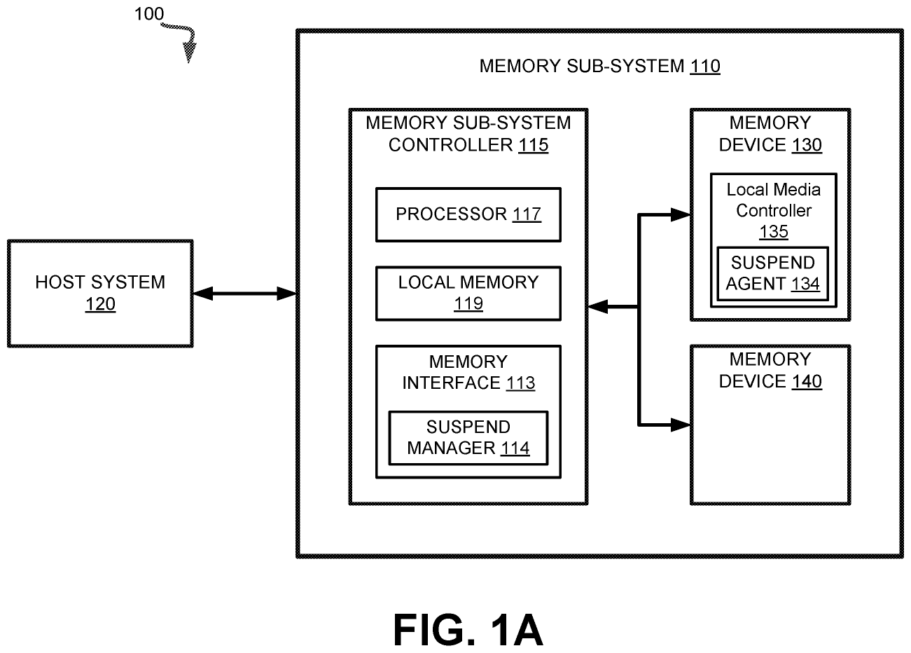

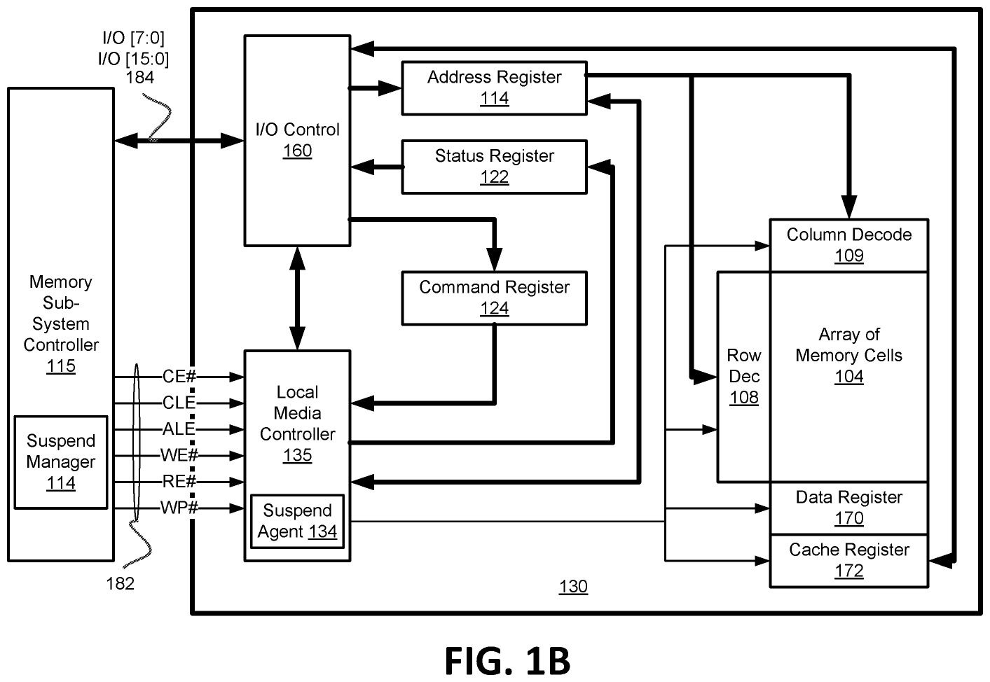

Aspects of the present disclosure are directed to resuming suspended program operations in a memory device of a memory sub-system. A memory sub-system can be a storage device, a memory module, or a hybrid of a storage device and memory module. Examples of storage devices and memory modules are described below in conjunction with FIG. 1. In general, a host system can utilize a memory sub-system that includes one or more components, such as memory devices that store data. The host system can provide data to be stored at the memory sub-system and can request data to be retrieved from the memory sub-system.

A memory sub-system can include high density non-volatile memory devices where retention of data is desired when no power is supplied to the memory device. For example, NAND memory, such as 3D flash NAND memory, offers storage in the form of compact, high density configurations. A non-volatile memory device is a package of one or more dice, each including one or more planes. For some types of non-volatile memory devices (e.g., NAND memory), each plane includes a set of physical blocks. Each block includes a set of pages. Each page includes a set of memory cells (“cells”). A cell is an electronic circuit that stores information. Depending on the cell type, a cell can store one or more bits of binary information, and has various logic states that correlate to the number of bits being stored. The logic states can be represented by binary values, such as “0” and “1”, or combinations of such values.

A memory device can be made up of bits arranged in a two-dimensional or a three-dimensional grid. Memory cells are formed onto a silicon wafer in an array of columns (also hereinafter referred to as bitlines) and rows (also hereinafter referred to as wordlines). A wordline can refer to one or more rows of memory cells of a memory device that are used with one or more bitlines to generate the address of each of the memory cells. The intersection of a bitline and wordline constitutes the address of the memory cell. A block hereinafter refers to a unit of the memory device used to store data and can include a group of memory cells, a wordline group, a wordline, or individual memory cells. One or more blocks can be grouped together to form separate partitions (e.g., planes) of the memory device in order to allow concurrent operations to take place on each plane. The memory device can include circuitry that performs concurrent memory page accesses of two or more memory planes. For example, the memory device can include multiple access line driver circuits and power circuits that can be shared by the planes of the memory device to facilitate concurrent access of pages of two or more memory planes, including different page types. For ease of description, these circuits can be generally referred to as independent plane driver circuits. Depending on the storage architecture employed, data can be stored across the memory planes (i.e. in stripes). Accordingly, one request to read a segment of data (e.g., corresponding to one or more data addresses), can result in read operations performed on two or more of the memory planes of the memory device.

In certain memory sub-systems it is quite common to receive a request to perform a memory access operation, such as a program operation of data from a host system, and then to subsequently receive a request to perform another memory access operation, such as a read operation on that same data from the host system right away, possibly even before the program operation has been completed. Conventional memory sub-systems sometimes keep the data being programmed in controller memory (e.g., dynamic random access memory (DRAM)) while the underlying memory device (e.g., negative-and (NAND) type flash memory) of the memory sub-system is being programmed, and then flush the controller memory when the program operation is complete. As long as the programming time (i.e., the time associated with performing the program operation of the memory device) is relatively short, a controller memory of reasonable size can accommodate the program data. When the memory device uses certain types of memory cells, such as triple level cells (TLCs) or quad-level cells (QLCs), however, the programming times can increase significantly. As such, the command latency time associated with the subsequently received memory access commands is increased significantly. If a subsequent request to perform a read operation is received while the program operation is still ongoing, certain memory sub-systems must wait until the program operation is complete before performing the read operation on the memory device. This can lead to significant latency in responding to requests from the host system.

In order to reduce latency in mixed workloads (e.g., a combination of program operations and read operations, such as a program operation followed immediately by a read operation), certain memory sub-systems utilize a program suspend protocol to allow subsequently received memory access commands (e.g., read operations) to access a page of a memory device on which a program operation is currently being performed. The program suspend protocol can use the memory device to temporarily pause the program operation to allow access to the memory array. In particular, when the memory sub-system receives a request to perform a memory access operation on data stored in a page of the memory device while a program operation (e.g., a TLC program operation) is in progress, a suspend manager of the memory sub-system controller can issue a specific program suspend command which causes the memory device to enter a suspend state, during which the ongoing program operation is temporarily suspended (e.g., paused). These memory devices, and their associated suspend protocols, can permit certain types of operations (e.g., read operations), to be performed while the memory device is in the suspend state. Once completed, the memory device can return to a normal operating state and resume the paused program operation.

During the period of time when the memory device is in the suspend state, the memory cells that were partially programmed with data before the program operation was suspended can experience certain forms of charge loss, such as quick charge loss (QCL). Since the level of charge stored in those cells decreases, the cells may not pass a program verify operation performed when the program operation is resumed. The program verify operation can be performed to determine whether the memory cells have reached a target voltage level and whether additional programming is needed. For example, during the program verify operation the level of charge stored at the cell is read and compared to an expected charge level. Due to the charge loss experienced while the program operation is suspended, certain memory cells may have a level of charge that is below that expected charge level. Accordingly, the memory device may cause an additional programming pulse to be applied to those cells to increase the charge level. The magnitude of such a pulse is typically fixed according to certain trim settings of the memory device and can cause the level of charge to exceed the expected charge level, thereby hurting a read window budget (RWB) for programming distributions in the memory device.

In addition, when a program operation is suspended multiple times before it is completed, there can be an impact on the memory cells of other wordlines in the memory array of the memory device. For example, when the program operation is being performed on memory cells associated with a selected wordline WLn, repeatedly suspending the program operation can negatively impact the margins of an erase distribution of memory cells associated with WLn+3. As noted above, each time the program operation is suspended, additional programming pulses are applied to the selected wordline, including for example in a seeding phase or a seeding anticipation phase of the program operation. In addition, other bias voltages are applied to other wordlines in the memory array. The specific pattern of these bias voltages (e.g., pass voltages) can create a relatively large channel potential difference between WLn+3 and WLn+4. As a result of this channel potential difference, an increased amount of hot-electron (“hot-e”) disturb can occur where residue electrons are injected from a drain depletion region into the floating gate, thereby reducing the margins of the memory cells associated with WLn+3 which are programmed to the erase state. In addition, this channel potential differential can initiate an electrostatic field of sufficient magnitude to change the charge on the selected wordline and cause the contents of the memory cell to be programmed inadvertently or read incorrectly. Furthermore, the electrostatic field can cause local electron-hole pair generation in the channel region, leading to even more electrons that can be injected into the selected word line.

Certain memory devices attempt to address the charge loss and decreased read margins that result from repeatedly resuming suspended program operations by causing a negative voltage offset to be applied to the programming pulse when the program operations are resumed. This negative voltage offset reduces the magnitude of the programming pulse, which can reduce the programming voltage overshoot and associated margin loss. The amount of charge loss varies from cell to cell, however, and there are varying degrees of voltage overshoot on memory cells being programmed to different programming levels. Thus, a single negative voltage offset applied to memory cells being programmed to all different programming levels can be sub-optimal and ultimately increase the total number of programming pulses applied to the memory device, potentially eliminating any benefit in the read margins, especially in the erase distribution of memory cells associated with the selected wordline. In addition, most memory devices do not have any practical solution for the negative impact on other wordlines (e.g., WLn+3) in the memory array

Aspects of the present disclosure address the above and other deficiencies by providing a novel technique for resuming suspended program operations in a memory device in order to mitigate margin degradation for memory cells in the erase state. In one embodiment, responsive to receiving a request to resume a previously suspended memory access operation, control logic on the memory device can initiate a program verify operation on a memory cell of the memory device, such as a memory cell that was at least partially programmed during the previously suspended memory access operation. The control logic can further determine whether the memory cell passes the program verify operation. Responsive to determining that the memory cell does not pass the program verify operation, the control logic can identify a program level group of a plurality of program level groups with which the memory cell is associated and determine a resume program offset value associated with the program level group, wherein each of the plurality of program level groups has a different respective resume program offset value. The control logic can further cause a programming pulse to be applied to the memory cell to resume the previously suspended memory access operation, wherein a magnitude of the programming pulse is based on the resume program offset value associated with the program level group.

In addition, when a request to suspend performance of a program operation being performed on the memory device is received, the control logic on the memory device can make a determination of whether the program operation is in a program verify phase. Certain program operations can include a plurality of program phases, each followed by a respective program verify phase. In response to determining that the program operation is in a program verify phase at the time when the request is to suspend is received, the control logic can complete performance of the program verify phase and then cause the memory device to enter a suspend state without entering a seeding anticipation phase associated with a subsequent program phase. The program operation is suspended during the suspend state, so that another memory access operation (e.g., a read operation) can be performed.

Advantages of this approach include, but are not limited to, improved performance in the memory sub-system. In the manner described herein, the latency associated with completion of subsequently received memory access commands with lower operation times can be reduced as performance of those operations need not wait for completion of ongoing memory access operations with higher operation times. This suspend functionality can be implemented without increasing margin degradation for the erase distributions of memory cells and without increasing hot-electron injection on other wordlines in the memory array. Accordingly, the overall quality of service level of the memory sub-system is improved without imposing any penalties in performance or reliability. In addition, bypassing the seeding anticipation phase when the program operation is suspended during a program verify phase, saves time and reduces the negative impact on the margins of the erase distribution of memory cells associated with other wordlines in the memory array.

FIG. 1A illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to different types of memory sub-system 110. FIG. 1A illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access the memory components (e.g., memory devices 130) when the memory sub-system 110 is coupled with the host system 120 by the PCIe interface. The physical host interface can provide an interface for passing control, address, data, and other signals between the memory sub-system 110 and the host system 120. FIG. 1A illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include negative-and (NAND) type flash memory and write-in-place memory, such as three-dimensional cross-point (“3D cross-point”) memory. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130 can include one or more arrays of memory cells. One type of memory cell, for example, single level cells (SLC) can store one bit per cell. Other types of memory cells, such as multi-level cells (MLCs), triple level cells (TLCs), and quad-level cells (QLCs), can store multiple bits per cell. In some embodiments, each of the memory devices 130 can include one or more arrays of memory cells such as SLCs, MLCs, TLCs, QLCs, or any combination of such. In some embodiments, a particular memory device can include an SLC portion, and an MLC portion, a TLC portion, or a QLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), negative-or (NOR) flash memory, electrically erasable programmable read-only memory (EEPROM).

A memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processor 117 (e.g., a processing device) configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1A has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical address (e.g., logical block address (LBA), namespace) and a physical address (e.g., physical block address) that are associated with the memory devices 130. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some embodiments, the memory devices 130 include local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, a memory device 130 is a managed memory device, which is a raw memory device 130 having control logic (e.g., local controller 135) on the die and a controller (e.g., memory sub-system controller 115) for media management within the same memory device package. An example of a managed memory device is a managed NAND (MNAND) device. Memory device 130, for example, can represent a single die having some control logic (e.g., local media controller 135) embodied thereon. In some embodiments, one or more components of memory sub-system 110 can be omitted.

In one embodiment, the memory sub-system 110 includes a memory interface component 113, which includes suspend manager 114. Memory interface component 113 is responsible for handling interactions of memory sub-system controller 115 with the memory devices of memory sub-system 110, such as memory device 130. For example, memory interface component 113 can send memory access commands corresponding to requests received from host system 120 to memory device 130, such as program commands, read commands, or other commands. In addition, memory interface component 113 can receive data from memory device 130, such as data retrieved in response to a read command or a confirmation that a program command was successfully performed. In some embodiments, the memory sub-system controller 115 includes at least a portion of the memory interface 113. For example, the memory sub-system controller 115 can include a processor 117 (processing device) configured to execute instructions stored in local memory 119 for performing the operations described herein. In some embodiments, the memory interface component 113 is part of the host system 110, an application, or an operating system. In one embodiment, memory interface 113 includes suspend manager 114, among other sub-components. Suspend manager 114 can direct specific commands, including suspend and resume commands, to memory device 130 to manage collisions between different memory access operations. A collision can occur when a first memory access operation is being performed on cells of a certain data block, sub-block, and wordline of memory device 130 when a request to perform a second memory access operation on cells of the same data block, sub-block and wordline is received. In response to such a collision, suspend manager 114 can determine how to proceed. In one embodiment, suspend manager 114 can suspend the first memory access operation (e.g., a program operation) by issuing a designated suspend command to memory device 130 and then issuing a request to perform a second memory access operation (e.g., a read operation) while the first memory access operation is suspended. Further details with regards to the operations of suspend manager 114 are described below.

In one embodiment, memory device 130 includes a suspend agent 134 configured to carry out corresponding memory access operations, in response to receiving the memory access commands from suspend manager 114. In some embodiments, local media controller 135 includes at least a portion of suspend agent 134 and is configured to perform the functionality described herein. In some embodiment, suspend agent 134 is implemented on memory device 130 using firmware, hardware components, or a combination of the above. In one embodiment, suspend agent 134 receives, from a requestor, such as suspend manager 114, a request to suspend performance of an ongoing memory access operation having a long operation time (e.g., a program operation). In response, the suspend agent 134 can cause memory device 130 to enter a suspend state, where the first memory access operation is suspended during the suspend state. Suspend agent can further receive one or more requests to perform additional memory access operations, such as a read operation, while the memory device 130 is in the suspend state. Suspend agent 134 can initiate the read operation and notify suspend manager 114 when the dynamic SLC program operation is complete, and the suspend manager 114 can send a request to resume the suspended memory access operation. In one embodiment, prior to resuming the suspected memory access operation, suspend agent 134 can identify a program level group of a plurality of program level groups with which a memory cell is associated and determine a resume program offset value associated with the program level group, wherein each of the plurality of program level groups has a different respective resume program offset value. Suspend agent 134 can further cause a programming pulse to be applied to the memory cell to resume the previously suspended memory access operation, wherein a magnitude of the programming pulse is based on the resume program offset value associated with the program level group. Further details with regards to the operations of suspend agent 134 are described below.

FIG. 1B is a simplified block diagram of a first apparatus, in the form of a memory device 130, in communication with a second apparatus, in the form of a memory sub-system controller 115 of a memory sub-system (e.g., memory sub-system 110 of FIG. 1A), according to an embodiment. Some examples of electronic systems include personal computers, personal digital assistants (PDAs), digital cameras, digital media players, digital recorders, games, appliances, vehicles, wireless devices, mobile telephones and the like. The memory sub-system controller 115 (e.g., a controller external to the memory device 130), may be a memory controller or other external host device. In one embodiment, memory sub-system controller 115 includes suspend manager 114.

Memory device 130 includes an array of memory cells 104 logically arranged in rows and columns. Memory cells of a logical row are typically connected to the same access line (e.g., a wordline) while memory cells of a logical column are typically selectively connected to the same data line (e.g., a bit line). A single access line may be associated with more than one logical row of memory cells and a single data line may be associated with more than one logical column. Memory cells (not shown in FIG. 1B) of at least a portion of array of memory cells 104 are capable of being programmed to one of at least two target data states.

Row decode circuitry 108 and column decode circuitry 109 are provided to decode address signals. Address signals are received and decoded to access the array of memory cells 104. Memory device 130 also includes input/output (I/O) control circuitry 160 to manage input of commands, addresses and data to the memory device 130 as well as output of data and status information from the memory device 130. An address register 114 is in communication with I/O control circuitry 160 and row decode circuitry 108 and column decode circuitry 109 to latch the address signals prior to decoding. A command register 124 is in communication with I/O control circuitry 160 and local media controller 135 to latch incoming commands.

A controller (e.g., the local media controller 135 internal to the memory device 130) controls access to the array of memory cells 104 in response to the commands and generates status information for the external memory sub-system controller 115, i.e., the local media controller 135 is configured to perform access operations (e.g., read operations, programming operations and/or erase operations) on the array of memory cells 104. The local media controller 135 is in communication with row decode circuitry 108 and column decode circuitry 109 to control the row decode circuitry 108 and column decode circuitry 109 in response to the addresses. In one embodiment, local media controller 135 includes suspend agent 134.

The local media controller 135 is also in communication with a cache register 172. Cache register 172 latches data, either incoming or outgoing, as directed by the local media controller 135 to temporarily store data while the array of memory cells 104 is busy writing or reading, respectively, other data. During a program operation (e.g., write operation), data may be passed from the cache register 172 to the data register 170 for transfer to the array of memory cells 104; then new data may be latched in the cache register 172 from the I/O control circuitry 160. During a read operation, data may be passed from the cache register 172 to the I/O control circuitry 160 for output to the memory sub-system controller 115; then new data may be passed from the data register 170 to the cache register 172. The cache register 172 and/or the data register 170 may form (e.g., may form a portion of) a page buffer of the memory device 130. A page buffer may further include sensing devices (not shown in FIG. 1B) to sense a data state of a memory cell of the array of memory cells 104, e.g., by sensing a state of a data line connected to that memory cell. A status register 122 may be in communication with I/O control circuitry 160 and the local memory controller 135 to latch the status information for output to the memory sub-system controller 115.

Memory device 130 receives control signals at the memory sub-system controller 115 from the local media controller 135 over a control link 182. For example, the control signals can include a chip enable signal CE #, a command latch enable signal CLE, an address latch enable signal ALE, a write enable signal WE #, a read enable signal RE #, and a write protect signal WP #. Additional or alternative control signals (not shown) may be further received over control link 182 depending upon the nature of the memory device 130. In one embodiment, memory device 130 receives command signals (which represent commands), address signals (which represent addresses), and data signals (which represent data) from the memory sub-system controller 115 over a multiplexed input/output (I/O) bus 184 and outputs data to the memory sub-system controller 115 over I/O bus 184.

For example, the commands may be received over input/output (I/O) pins [7:0] of I/O bus 184 at I/O control circuitry 160 and may then be written into command register 124. The addresses may be received over input/output (I/O) pins [7:0] of I/O bus 184 at I/O control circuitry 160 and may then be written into address register 114. The data may be received over input/output (I/O) pins [7:0] for an 8-bit device or input/output (I/O) pins [15:0] for a 16-bit device at I/O control circuitry 160 and then may be written into cache register 172. The data may be subsequently written into data register 170 for programming the array of memory cells 104.

In an embodiment, cache register 172 may be omitted, and the data may be written directly into data register 170. Data may also be output over input/output (I/O) pins [7:0] for an 8-bit device or input/output (I/O) pins [15:0] for a 16-bit device. Although reference may be made to I/O pins, they may include any conductive node providing for electrical connection to the memory device 130 by an external device (e.g., the memory sub-system controller 115), such as conductive pads or conductive bumps as are commonly used.

It will be appreciated by those skilled in the art that additional circuitry and signals can be provided, and that the memory device 130 of FIG. 1B has been simplified. It should be recognized that the functionality of the various block components described with reference to FIG. 1B may not necessarily be segregated to distinct components or component portions of an integrated circuit device. For example, a single component or component portion of an integrated circuit device could be adapted to perform the functionality of more than one block component of FIG. 1B. Alternatively, one or more components or component portions of an integrated circuit device could be combined to perform the functionality of a single block component of FIG. 1B. Additionally, while specific I/O pins are described in accordance with popular conventions for receipt and output of the various signals, it is noted that other combinations or numbers of I/O pins (or other I/O node structures) may be used in the various embodiments.

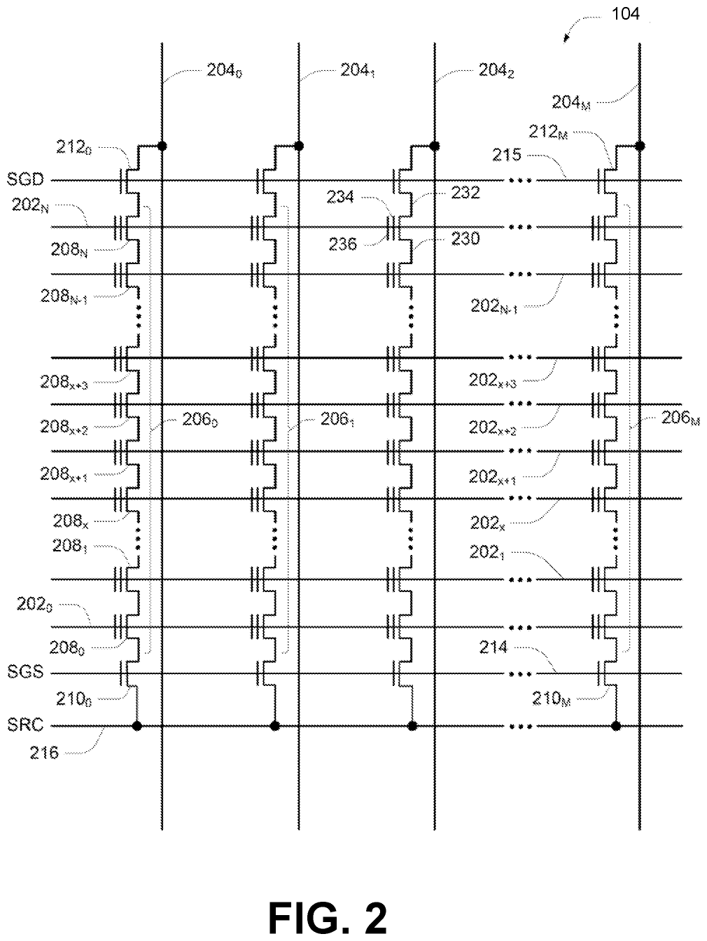

FIG. 2 is a schematic of portions of an array of memory cells 104, such as a NAND memory array, as could be used in a memory of the type described with reference to FIG. 1B according to an embodiment. Memory array 104 includes access lines, such as wordlines 202₀ to 202_{N}, and data lines, such as bit lines 204₀ to 204_{M}. The wordlines 202 can be connected to global access lines (e.g., global wordlines), not shown in FIG. 2, in a many-to-one relationship. For some embodiments, memory array 104 can be formed over a semiconductor that, for example, can be conductively doped to have a conductivity type, such as a p-type conductivity, e.g., to form a p-well, or an n-type conductivity, e.g., to form an n-well.

Memory array 104 can be arranged in rows (each corresponding to a wordline 202) and columns (each corresponding to a bit line 204). Each column can include a string of series-connected memory cells (e.g., non-volatile memory cells), such as one of NAND strings 206₀ to 206_{M}. Each NAND string 206 can be connected (e.g., selectively connected) to a common source (SRC) 216 and can include memory cells 208₀ to 208_{N}. The memory cells 208 can represent non-volatile memory cells for storage of data. The memory cells 208 of each NAND string 206 can be connected in series between a select gate 210 (e.g., a field-effect transistor), such as one of the select gates 210₀ to 210_{M} (e.g., that can be source select transistors, commonly referred to as select gate source), and a select gate 212 (e.g., a field-effect transistor), such as one of the select gates 212₀ to 212_{M} (e.g., that can be drain select transistors, commonly referred to as select gate drain). Select gates 210₀ to 210_{M} can be commonly connected to a select line 214, such as a source select line (SGS), and select gates 212₀ to 212_{M} can be commonly connected to a select line 215, such as a drain select line (SGD). Although depicted as traditional field-effect transistors, the select gates 210 and 212 can utilize a structure similar to (e.g., the same as) the memory cells 208. The select gates 210 and 212 can represent a number of select gates connected in series, with each select gate in series configured to receive a same or independent control signal.

A source of each select gate 210 can be connected to common source 216. The drain of each select gate 210 can be connected to a memory cell 208₀ of the corresponding NAND string 206. For example, the drain of select gate 210₀ can be connected to memory cell 208₀ of the corresponding NAND string 206₀. Therefore, each select gate 210 can be configured to selectively connect a corresponding NAND string 206 to the common source 216. A control gate of each select gate 210 can be connected to the select line 214.

The drain of each select gate 212 can be connected to the bit line 204 for the corresponding NAND string 206. For example, the drain of select gate 212₀ can be connected to the bit line 204₀ for the corresponding NAND string 206₀. The source of each select gate 212 can be connected to a memory cell 208_{N} of the corresponding NAND string 206. For example, the source of select gate 212₀ can be connected to memory cell 208_{N} of the corresponding NAND string 206₀. Therefore, each select gate 212 can be configured to selectively connect a corresponding NAND string 206 to the corresponding bit line 204. A control gate of each select gate 212 can be connected to select line 215.

The memory array 104 in FIG. 2 can be a quasi-two-dimensional memory array and can have a generally planar structure, e.g., where the common source 216, NAND strings 206 and bit lines 204 extend in substantially parallel planes. Alternatively, the memory array 104 in FIG. 2 can be a three-dimensional memory array, e.g., where NAND strings 206 can extend substantially perpendicular to a plane containing the common source 216 and to a plane containing the bit lines 204 that can be substantially parallel to the plane containing the common source 216.

Typical construction of memory cells 208 includes a data-storage structure 234 (e.g., a floating gate, charge trap, and the like) that can determine a data state of the memory cell (e.g., through changes in threshold voltage), and a control gate 236, as shown in FIG. 2. The data-storage structure 234 can include both conductive and dielectric structures while the control gate 236 is generally formed of one or more conductive materials. In some cases, memory cells 208 can further have a defined source/drain (e.g., source) 230 and a defined source/drain (e.g., drain) 232. The memory cells 208 have their control gates 236 connected to (and in some cases form) a wordline 202.

A column of the memory cells 208 can be a NAND string 206 or a number of NAND strings 206 selectively connected to a given bit line 204. A row of the memory cells 208 can be memory cells 208 commonly connected to a given wordline 202. A row of memory cells 208 can, but need not, include all the memory cells 208 commonly connected to a given wordline 202. Rows of the memory cells 208 can often be divided into one or more groups of physical pages of memory cells 208, and physical pages of the memory cells 208 often include every other memory cell 208 commonly connected to a given wordline 202. For example, the memory cells 208 commonly connected to wordline 202_{N} and selectively connected to even bit lines 204 (e.g., bit lines 204₀, 204₂, 204₄, etc.) can be one physical page of the memory cells 208 (e.g., even memory cells) while memory cells 208 commonly connected to wordline 202_{N} and selectively connected to odd bit lines 204 (e.g., bit lines 204₁, 204₃, 204₅, etc.) can be another physical page of the memory cells 208 (e.g., odd memory cells).

Although bit lines 204₃-204₅ are not explicitly depicted in FIG. 2, it is apparent from the figure that the bit lines 204 of the array of memory cells 104 can be numbered consecutively from bit line 204₀ to bit line 204_{M}. Other groupings of the memory cells 208 commonly connected to a given wordline 202 can also define a physical page of memory cells 208. For certain memory devices, all memory cells commonly connected to a given wordline can be deemed a physical page of memory cells. The portion of a physical page of memory cells (which, in some embodiments, could still be the entire row) that is read during a single read operation or programmed during a single programming operation (e.g., an upper or lower page of memory cells) can be deemed a logical page of memory cells. A block of memory cells can include those memory cells that are configured to be erased together, such as all memory cells connected to wordlines 202₀-202_{N} (e.g., all NAND strings 206 sharing common wordlines 202). Unless expressly distinguished, a reference to a page of memory cells herein refers to the memory cells of a logical page of memory cells. Although the example of FIG. 2 is discussed in conjunction with NAND flash, the embodiments and concepts described herein are not limited to a particular array architecture or structure, and can include other structures (e.g., SONOS, phase change, ferroelectric, etc.) and other architectures (e.g., AND arrays, NOR arrays, etc.).

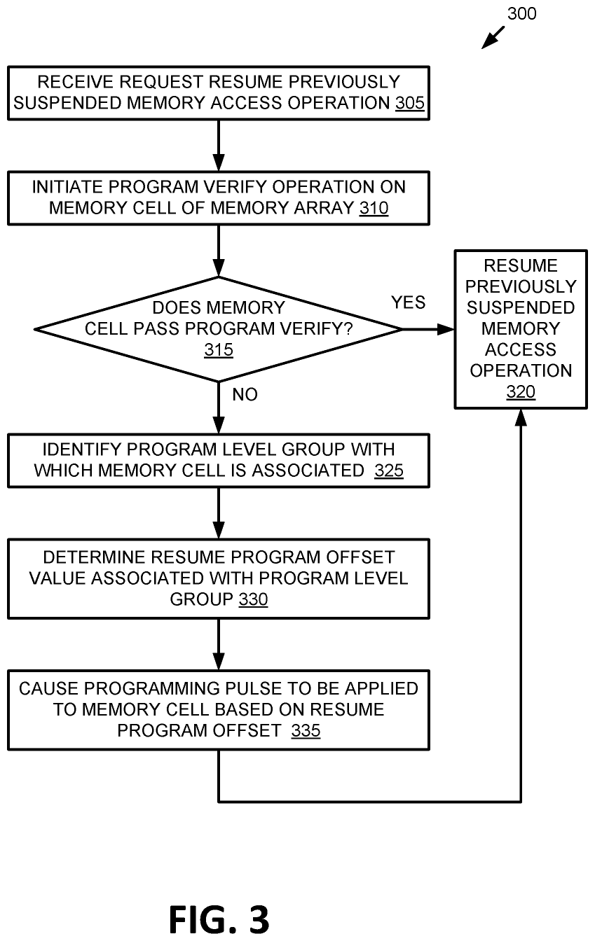

FIG. 3 is a flow diagram of an example method of resuming suspended program operations in a memory device of a memory sub-system in accordance with some embodiments of the present disclosure. The method 300 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 300 is performed by local media controller 135 and/or suspend agent 134 of FIG. 1A and FIG. 1B. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 305, a request is received. For example, control logic (e.g., local media controller 135) can receive, from a requestor such as memory interface of 113 of memory sub-system controller 115, a request to resume a previously suspended memory access operation being performed on the memory array of memory device 130. In one embodiment, suspend manager 114 sends a request to resume the memory access operation, such as a resume command, to memory device 130, which is received by suspend agent 134. In one embodiment, the previously suspended memory access operation comprises a program operation that was suspended for a period of time in response to a request to suspend the program operation. In one embodiment, some other memory access operation, such as a read operation was performed on the memory array of memory device 130 during the period of time for which the program operation was suspended. Upon completion of the read operation, suspend agent 134 may have provided a notification to suspend manager 114 to indicate that the read operation was completed, where such notification triggered suspend manager 114 to send the request to resume the previously suspended program operation.

At operation 310, the programmed memory cells are verified. For example, the control logic can initiate a program verify operation. In one embodiment, the program verify operation is initiated in response to receiving the request to resume the previously suspended memory access operation (e.g., the program operation). In one embodiment, during the program verify operation, the control logic causes a read voltage to be applied to a selected wordline associated with the memory cell to be verified (i.e., a selected memory cell) to determine a level of charge stored at the selected memory cell to confirm whether the desired value was properly programmed.

At operation 315, a determination is made. For example, the control logic can determine whether the selected memory cell passes the program verify operation. In one embodiment, the control logic compares the determined level of charge at the selected memory cell to a threshold voltage level (e.g., a target voltage). If the determined level of charge is greater than or equal to the threshold voltage level, the control logic can determine that the memory cell passes the program verify operation. If, however, the determined level of charge is less than the threshold voltage level (e.g., due to quick charge loss that occurred during the period of time for which the program operation was suspended), the control logic can determine that the memory cell does not pass the program verify operation.

At operation 320, the previously suspended memory access operation is resumed. For example, responsive to determining that the memory cell passes the program verify operation the control logic can cause memory device 130 to exit the suspend state and resume the previously suspended memory access operation at a point where the program operation left off using stored progress information associated with the program operation. In one embodiment, suspend agent 134 can read the data (e.g., from a page cache on memory device 130, which was previously written to the memory array, and compare that data to the data in the resume request to determine where the memory access operation left off when suspended. Suspend agent 134 can thus resume programming the data for the program operation to the memory array from that point.

If, however, it is determined that the memory cell does not pass the program verify operation, at operation 325, a program level group is identified. For example, the control logic can identify a program level group of a plurality of program level groups with which the selected memory cell is associated. In one embodiment, each of the program level groups includes one or more programming levels to which memory cells in the memory device can be programmed. For example, in a QLC memory device, there can be sixteen programming levels (i.e., L0-L15), while in a TLC memory device, there can be eight programming levels (i.e., L0-L7). In one embodiment, each programming level could be in a separate program level group (i.e., sixteen program level groups for QLC memory and eight program level groups for TLC memory). In other embodiments, there can be multiple programming levels in each program level group, such as two, four, eight, or some other number of programming levels per program level group. For example, for a TLC memory device there could be two program level groups where a first group includes programming levels L1, L2, L3 and a second group includes programming levels L4, L5, L6, L7 (where L0 is the erase state and thus not part of either program level group). In other embodiments, any other arrangement of program level groups is possible. In addition, since the charge loss can vary between memory cells associated with different wordlines in the memory array, there can be different program level groups for different wordlines as well. Thus, in order to identify the program level group with which the selected memory cell is associated, the control logic can determine a programming level to which the memory cell was to be programmed as part of the previously suspended memory access operation, and identify the corresponding program level group (e.g., from a table or other data structure maintained on memory device 130 or elsewhere in memory sub-system 110).

At operation 330, a resume program offset value is determined. For example, the control logic can determine a resume program offset value associated with the determined program level group. In one embodiment, each of the plurality of program level groups has a different respective resume program offset value. In one embodiment, the control logic can access a corresponding entry of a plurality of entries in a data structure maintained on memory device 130 or elsewhere in memory sub-system 110. Each of the plurality of entries can be associated with a respective program level group of the plurality of program level groups and comprises a respective resume program offset value. In one embodiment, the expected charge loss at each programming level during the period of time for which a program operation is suspended can be characterized through experimentation and a corresponding resume program offset value can be determined that reflects how to account for that expected charge loss. The data structure can be programmed with these resume program offset values for each program level group, so that they can be accessed in response to resuming a previously memory access operation. In one embodiment, lower programming levels typically experience a lower level of charge loss, and thus can have a larger amount of negative resume program offset. Conversely, higher programming levels typically experience a higher level of charge loss, and thus can have a smaller amount of negative resume program offset.

At operation 335, a programing pulse is applied. For example, the control logic can cause a programming pulse to be applied to the wordline associated with the selected memory cell to resume the previously suspended memory access operation. In one embodiment, the magnitude of the programming pulse is based on the resume program offset value associated with the determined program level group. For example, a program pulse may have a default voltage magnitude, which can be reduced, however, to an adjusted magnitude appropriate for a given programming level via application of the corresponding resume program offset value. This program pulse can raise the level of charge at the selected memory cell to the expected level (i.e., the level it would have been at before the program operation was suspended, without overshooting this expected level.

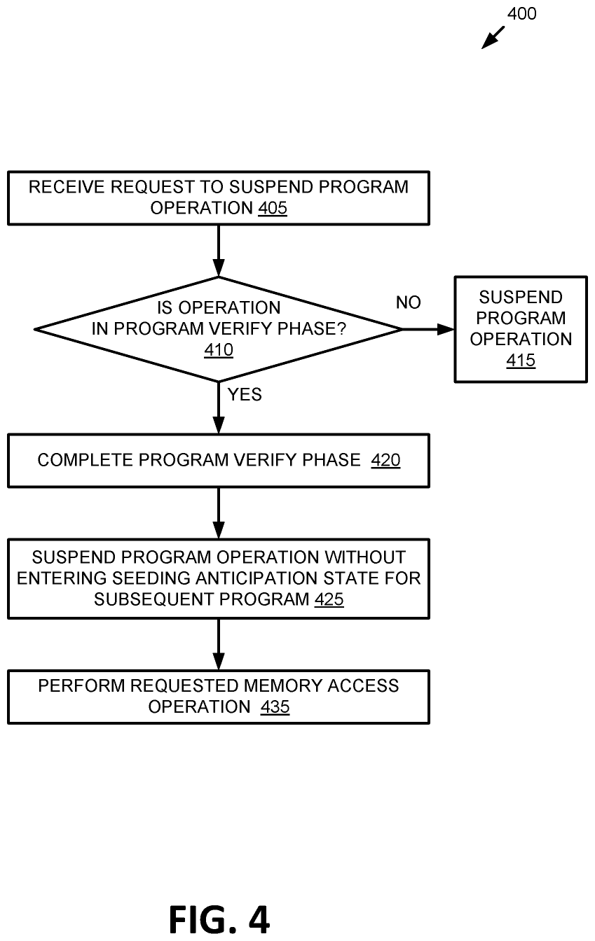

FIG. 4 is a flow diagram of an example method of suspending program operations in a memory device of a memory sub-system in accordance with some embodiments of the present disclosure. The method 400 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 400 is performed by local media controller 135 and/or suspend agent 134 of FIG. 1A and FIG. 1B. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 405, a request is received. For example, control logic (e.g., local media controller 135) can receive, from a requestor such as memory interface of 113 of memory sub-system 110, a request to suspend performance of a program operation being performed on the memory array of a memory device, such as memory device 130. In one embodiment, suspend manager 114 sends a request to suspend the program operation, such as a suspend command, to memory device 130, which is received by suspend agent 134.

At operation 410, a determination is made. For example, the control logic can determine whether the program operation is in a program verify phase at a time when the request to suspend is received. In one embodiment, the program operation includes a plurality of program phases and a plurality of program verify phases, wherein a respective program verify phase follows each of the plurality of program phases to confirm whether the selected memory cell was properly programmed to a desired voltage level. Depending on the timing of the request to suspend performance of the program operation, the program operation can be in either a program phase, a program verify phase, or some other phase.

Responsive to determining that the program operation is not in the program verify phase, at operation 415, the control logic causes the memory device to enter the suspend state. In one embodiment, the program operation is suspended (i.e., paused, stopped, halted) during the suspend state. In one embodiment, suspend agent 134 stores progress information associated with the program operation in a page cache or other location in memory device 130. For example, suspend agent 134 can store data already programmed to memory array responsive to entering the suspend state, where such data can be used to resume the suspended program operation at a later time.

Responsive to determining that the program operation is in the program verify phase, at operation 420, the control logic completes the program verify phase. In one embodiment, during the program verify phase, the control logic causes a read voltage to be applied to a selected wordline associated with the memory cell to be verified (i.e., a selected memory cell) to determine a level of charge stored at the selected memory cell to confirm whether the desired value was properly programmed.

At operation 425, the program operation is suspended. For example, the control logic causes the memory device to enter a suspend state without entering a seeding anticipation phase associated with a subsequent program phase. In one embodiment, the program operation is suspended (i.e., paused, stopped, halted) during the suspend state. Since, as noted above, the program operation includes a number of program phases, each followed by a respective program verify phase, certain memory devices proceed directly to a seeding anticipation phase for the next program phase upon completion of the previous program verify phase. Seeding includes the application of a seeding voltage to the memory string to raise the channel potential prior to each program phase in order to allow the memory cells to reach the desired voltage level more quickly. Rather, than performing such a seeding anticipation phase prior to suspending the program operation, the control logic can instead proceed directly to an array discharge operation upon completion of the program verify phase.

At operation 435, a memory access operation is performed. For example, while the memory devices is in the suspend state, the control logic can receive a request to perform another memory access operation, such as a read operation or other operation. In response, the control logic can initiate that memory access operation, such as by causing appropriate voltage signals to be applied to the corresponding wordlines of the memory array of memory device 130. Upon completion of the memory access operation, the control logic can notify the requestor, and optionally receive a request to resume the previously suspended program operation. In one embodiment, the control logic can proceed with resuming the program operation according to the operations of method 300 described above with respect to FIG. 3.

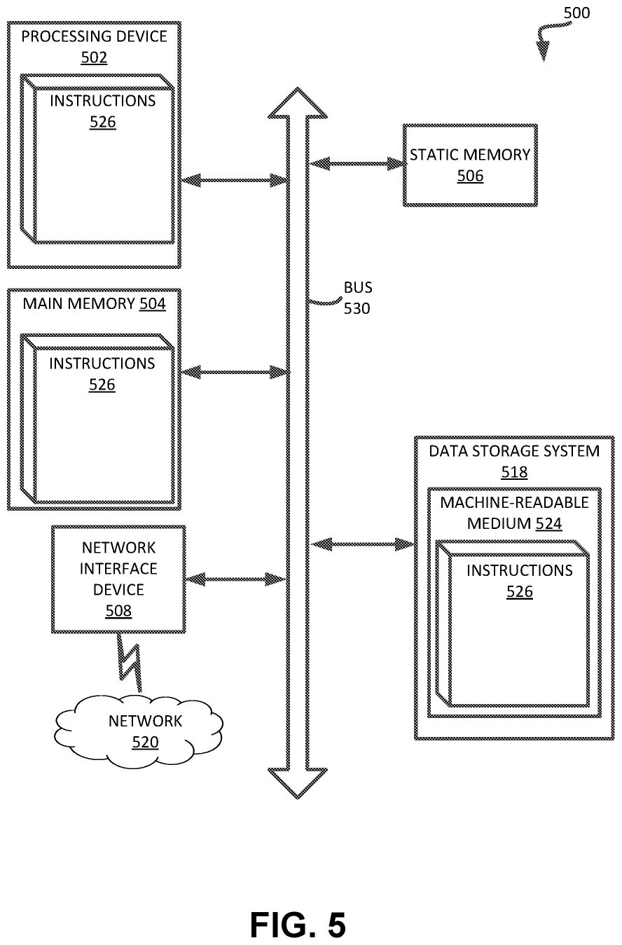

FIG. 5 illustrates an example machine of a computer system 500 within which a set of instructions, for causing the machine to perform any one or more of the methodologies discussed herein, can be executed. In some embodiments, the computer system 500 can correspond to a host system (e.g., the host system 120 of FIG. 1) that includes, is coupled to, or utilizes a memory sub-system (e.g., the memory sub-system 110 of FIG. 1) or can be used to perform the operations of a controller (e.g., to execute an operating system to perform operations corresponding to the local media controller 135 of FIG. 1). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 500 includes a processing device 502, a main memory 504 (e.g., read-only memory (ROM), flash memory, dynamic random access memory (DRAM) such as synchronous DRAM (SDRAM) or Rambus DRAM (RDRAM), etc.), a static memory 506 (e.g., flash memory, static random access memory (SRAM), etc.), and a data storage system 518, which communicate with each other via a bus 530.

Processing device 502 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 502 can also be one or more special-purpose processing devices such as an application specific integrated circuit (ASIC), a field programmable gate array (FPGA), a digital signal processor (DSP), network processor, or the like. The processing device 502 is configured to execute instructions 526 for performing the operations and steps discussed herein. The computer system 500 can further include a network interface device 508 to communicate over the network 520.

The data storage system 518 can include a machine-readable storage medium 524 (also known as a computer-readable medium) on which is stored one or more sets of instructions 526 or software embodying any one or more of the methodologies or functions described herein. The instructions 526 can also reside, completely or at least partially, within the main memory 504 and/or within the processing device 502 during execution thereof by the computer system 500, the main memory 504 and the processing device 502 also constituting machine-readable storage media. The machine-readable storage medium 524, data storage system 518, and/or main memory 504 can correspond to the memory sub-system 110 of FIG. 1.

In one embodiment, the instructions 526 include instructions to implement functionality corresponding to the local media controller 135 of FIG. 1. While the machine-readable storage medium 524 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A memory device comprising:
a memory array; and
control logic, operatively coupled with the memory array, to perform operations comprising:
responsive to receiving a request to resume a previously suspended memory access operation, initiating a program verify operation on a memory cell of the memory array, wherein the memory cell is associated with the previously suspended memory access operation;
determining whether the memory cell passes the program verify operation; and
responsive to determining that the memory cell does not pass the program verify operation:
identifying a program level group of a plurality of program level groups with which the memory cell is associated;
determining a resume program offset value associated with the program level group, wherein each of the plurality of program level groups has a different respective resume program offset value; and
causing a programming pulse to be applied to the memory cell to resume the previously suspended memory access operation, wherein a magnitude of the programming pulse is based on the resume program offset value associated with the program level group.

2. The memory device of claim 1, wherein initiating the program verify operation on the memory cell comprises causing a read voltage to be applied to the memory cell to determine a level of charge stored at the memory cell.

3. The memory device of claim 2, wherein determining whether the memory cell passes the program verify operation comprises determining whether the level of charge stored at the memory cell is greater than or equal to a threshold voltage level.

4. The memory device of claim 1, wherein identifying the program level group of a plurality of program level groups comprises:
determining a programming level of a plurality of programming levels to which the memory cell was to be programmed as part of the previously suspended memory access operation, wherein each of the plurality of program level groups is associated with one or more of the plurality of programming levels.

5. The memory device of claim 1, wherein determining the resume program offset value associated with the program level group comprises accessing a corresponding entry of a plurality of entries in a data structure, wherein each of the plurality of entries is associated with a respective program level group of the plurality of program level groups and comprises a respective resume program offset value.

6. The memory device of claim 1, wherein the previously suspended memory access operation comprises a program operation, and wherein the program operation was suspended for a period of time in response to a request to suspend the program operation, and wherein a read operation was performed on the memory array during the period of time for which the program operation was suspended.

7. The memory device of claim 1, wherein the control logic is to perform operations further comprising:
responsive to determining that the memory cell passes the program verify operation, resuming the previously suspended memory access operation based on stored progress information associated with the previously suspended memory access operation.

8. A method comprising:
responsive to receiving a request to resume a previously suspended memory access operation, initiating a program verify operation on a memory cell of a memory array of a memory device, wherein the memory cell is associated with the previously suspended memory access operation;
determining whether the memory cell passes the program verify operation; and
responsive to determining that the memory cell does not pass the program verify operation:
identifying a program level group of a plurality of program level groups with which the memory cell is associated;
determining a resume program offset value associated with the program level group, wherein each of the plurality of program level groups has a different respective resume program offset value; and
causing a programming pulse to be applied to the memory cell to resume the previously suspended memory access operation, wherein a magnitude of the programming pulse is based on the resume program offset value associated with the program level group.

9. The method of claim 8, wherein initiating the program verify operation on the memory cell comprises causing a read voltage to be applied to the memory cell to determine a level of charge stored at the memory cell.

10. The method of claim 9, wherein determining whether the memory cell passes the program verify operation comprises determining whether the level of charge stored at the memory cell is greater than or equal to a threshold voltage level.

11. The method of claim 8, wherein identifying the program level group of a plurality of program level groups comprises:
determining a programming level of a plurality of programming levels to which the memory cell was to be programmed as part of the previously suspended memory access operation, wherein each of the plurality of program level groups is associated with one or more of the plurality of programming levels.

12. The method of claim 8, wherein determining the resume program offset value associated with the program level group comprises accessing a corresponding entry of a plurality of entries in a data structure, wherein each of the plurality of entries is associated with a respective program level group of the plurality of program level groups and comprises a respective resume program offset value.

13. The method of claim 8, wherein the previously suspended memory access operation comprises a program operation, and wherein the program operation was suspended for a period of time in response to a request to suspend the program operation, and wherein a read operation was performed on the memory array during the period of time for which the program operation was suspended.

14. The method of claim 8, further comprising:
responsive to determining that the memory cell passes the program verify operation, resuming the previously suspended memory access operation based on stored progress information associated with the previously suspended memory access operation.

15. A memory device comprising:
a memory array; and
control logic, operatively coupled with the memory array, to perform operations comprising:
receiving, from a requestor, a first request to suspend performance of a program operation being performed on the memory array;
determining whether the program operation is in a program verify phase at a time when the request to suspend is received; and
responsive to determining that the program operation is in the program verify phase:
completing performance of the program verify phase; and
causing the memory device to enter a suspend state without entering a seeding anticipation phase associated with a subsequent program phase, wherein the program operation is suspended during the suspend state.

16. The memory device of claim 15, wherein the program operation comprises a plurality of program phases and a plurality of program verify phases, and wherein a respective program verify phase follows each of the plurality of program phases.

17. The memory device of claim 15, wherein causing the memory device to enter the suspend state without entering the seeding anticipation phase comprises proceeding directly to an array discharge operation upon completion of the program verify phase.

18. The memory device of claim 15, wherein the requestor comprises a memory sub-system controller of a memory sub-system comprising the memory device.

19. The memory device of claim 15, wherein the control logic is to perform operations further comprising:
receiving, from the requestor, a second request to perform a memory access operation on the memory array while the program operation is suspended; and
initiating the memory access operation on the memory array.

20. The memory device of claim 15, wherein the control logic is to perform operations further comprising:
responsive to determining that the program operation is not in the program verify phase, causing the memory device to enter the suspend state.
